(19) United States
(12) Patent Application Publication
(10) Pub. No.: US 2007/0224354 A1
(43) Pub. Date: Sep. 27, 2007

(54) MOLD FOR MANUFACTURING DISPLAY DEVICE AND MANUFACTURING METHOD OF DISPLAY DEVICE USING THE SAME

(76) Inventor: Jae-hyuk CHANG, Incheon (KR)

Correspondence Address: MACPHERSON KWOK CHEN & HEID LLP, 2033 GATEWAY PLACE, SUITE 400, SAN JOSE, CA, 95110, US

(21) Appl. No.: 11/689,390

(22) Filed: Mar. 21, 2007

(30) Foreign Application Priority Data
Mar. 27, 2006 (KR) 10-2006-0027232

(51) Int. Cl. B05D 3/12; B05D 7/00; B28B 7/34

(52) U.S. Cl. 427/358; 427/407.1; 249/134; 425/174

(57) ABSTRACT

A method of manufacturing a display device which reduces errors in patterning an organic layer due to bubbles, comprises: providing a mother insulating substrate which comprises usage regions arranged in a matrix shape and a removal region formed between the usage regions; forming an organic layer on the mother insulating substrate; arranging a mold formed with a pattern part corresponding to the usage regions and a groove corresponding to at least a part of the removal region and formed in a grid shape, on the organic layer; moving a pressure means and sequentially pressing the mold to the organic layer; and separating the mold from the organic layer.

### CROSS-REFERENCE TO RELATED APPLICATIONS

This application claims the benefit of Korean Patent Application No. 2006-0027232, filed on Mar. 27, 2006, in the Korean Intellectual Property Office, the disclosure of which is incorporated herein by reference.

### BACKGROUND OF THE INVENTION

1. Field of the Invention

The present invention relates to a mold for manufacturing a display device and a method of manufacturing a display device using the same.

2. Description of the Related Art

Flat panel displays such as organic light emitting diode (OLED) displays have replaced cathode ray tubes. However, many organic layers, e.g., patterned photosensitive layers are required to manufacture such display devices. Conventionally, the organic layers are patterned through exposure by using a mask. However, exposure equipment is expensive and the organic layers do not have good reproducibility.

An imprint method has been developed to pattern an organic layer. The imprint method uses a mold which is formed with a desired pattern and has several advantages in that the required equipment is not expensive, the production process is simple, and less time is required for patterning the organic layer. However, the imprint method may allow a bubble to become trapped between the mold and the organic layer while being pressed resulting in errors in patterning the organic layer.

### SUMMARY OF THE INVENTION

Accordingly, it is an aspect of the present invention to provide a method of manufacturing a display device which reduces errors in patterning an organic layer due to trapped bubbles.

It is another aspect of the present invention to provide a mold for manufacturing a display device which reduces errors in patterning an organic layer.

According to an aspect of the present invention a display device may be manufactured by: providing a mother insulating substrate having usage regions arranged in a matrix shape, and a removal region formed between the usage regions; forming an organic layer on the mother insulating substrate; arranging a mold formed with a pattern part corresponding to the usage regions and a groove corresponding to at least a part of the removal region on the organic layer; moving a pressure means and sequentially pressing the mold and formed in a grid shape to the organic layer; and separating the mold from the organic layer.

According to the embodiment of the present invention, the direction of motion of the pressure means maintaining a predetermined angle with respect to the extension direction of the groove.

According to the embodiment of the present invention, the direction of motion of the pressure means is perpendicular to the extension direction of the groove.

According to the embodiment of the present invention, the pressure means comprises a roller.

According to the embodiment of the present invention, the organic layer comprises a photosensitive material.

According to the embodiment of the present invention, the mold comprises a mold main body which comprises light transmitting polymer and a light blocking layer formed on the mold main body to correspond to the removal region.

According to the embodiment of the present invention, the light blocking layer is provided within the groove.

According to the embodiment of the present invention, the mold main body comprises polydimethylsiloxane (PDMS) or polycarbonate (PC).

According to the embodiment of the present invention, the method further comprises: exposing the organic layer to light by using the mold pressed to the organic layer as a mask.

According to the embodiment of the present invention, the depth of the groove is 100 percent to 500 percent of the thickness of the organic layer.

According to the embodiment of the present invention, the mold is pressed to the organic layer at a normal pressure.

According to an embodiment of the present invention, the method further comprises: forming a thin film transistor having a drain electrode and an organic layer on the mother insulating substrate.

According to the embodiment of the present invention, the pattern part has a concave embossing pattern and a protruding part corresponding to the drain electrode.

According to the embodiment of the present invention, an end part of the protruding part contacts the drain electrode while the mold is pressed to the organic layer.

According to the embodiment of the present invention, the mold further comprises: a light blocking layer formed in the groove.

According to the embodiment of the present invention, the mold main body comprises polymer.

According to the embodiment of the present invention, the mold main body is light-transmissive.

### BRIEF DESCRIPTION OF THE DRAWINGS

The above and/or other aspects and advantages of the present invention will become apparent and more readily appreciated from the following description of the embodiments, taken in conjunction with the accompanying drawings in which:

FIG. 1 is a cross-sectional view of a liquid crystal display (LCD) device which is manufactured according to the present invention;

FIGS. 2a to 8b illustrate a manufacturing method of a liquid crystal display (LCD) device according to a first embodiment of the present invention;

FIG. 9 illustrates another manufacturing method of the LCD device according to the first embodiment of the present invention;

FIG. 10 illustrates another manufacturing method of the LCD device according to the first embodiment of the present invention; and

FIG. 11 is a perspective view of another mold which is used to manufacture the LCD device according to the present invention.

### DETAILED DESCRIPTION OF EMBODIMENTS

Hereinafter, a term of “on” means that a new layer (i.e., film) may be interposed or not interposed between two layers (i.e., films), and a term of “directly on” means that two layers (i.e. films) are in contact with each other.

Hereinafter, a liquid crystal display (LCD) device will be described as an example of a display device. The present invention can be further applicable to other display devices such as an organic light emitting diode (OLED) device, an electro phoretic display device, a plasma display device, etc.

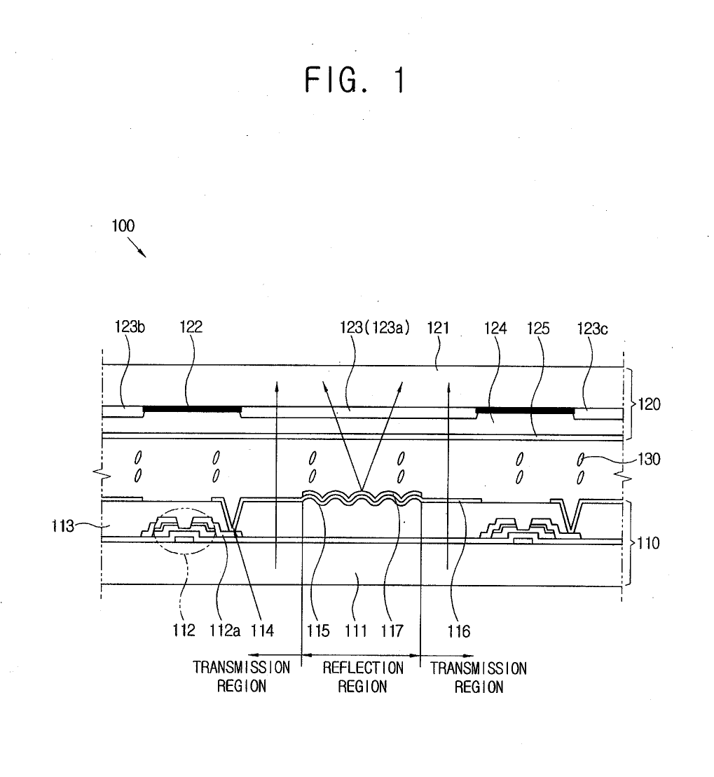

FIG. 1 is a cross-sectional view of a liquid crystal display (LCD) device which is manufactured according to the present invention.

A liquid crystal display (LCD) device 100 which is manufactured according to the present invention comprises a thin film transistor substrate 110, a color filter substrate 120 and a liquid crystal layer 130 which is interposed between the thin film transistor substrate 110 and the color filter substrate 120.

A plurality of thin film transistors 112 is formed on a first insulating substrate 111 of the thin film transistor substrate 110. Each thin film transistors 112 comprises a drain electrode 112a. The thin film transistor 112 in FIG. 1 employs an amorphous silicon layer as a semiconductor layer.

The thin film transistor 112 is covered by an organic layer 113 which is partially removed to form a contact hole 114. The drain electrode 112a is exposed through the contact hole 114. An embossing pattern 115 is formed in a part of the organic layer 113.

A pixel electrode 116 is made of a transparent conductive material, and is connected with the thin film transistor 112 through the contact hole 114 on the organic layer 113. Typically, the pixel electrode 116 is made of metal oxide such as indium tin oxide (ITO) or indium zinc oxide (IZO).

A reflection layer 117 is formed on the pixel electrode 116 disposed in the embossing pattern 115. The reflection layer 117 may comprise a metal which has a high reflection rate, such as aluminum, silver or aluminum-molybdenum alloy. Since the reflection layer 117 is formed on the embossing pattern 115, the reflection layer 117 has an uneven part according to the shape of the embossing pattern 115. A pixel is divided into a reflection region formed with the reflection layer 117 and a transmission region surrounding the reflection region, by the reflection layer 117.

A black matrix 122 has a grid pattern and is formed on a second insulating substrate 121 of the color filter substrate 120. The black matrix 122 may comprise an organic material having a black pigment. The black matrix 122 is formed to correspond to the thin film transistor 112 of the thin film transistor substrate 110 and a wiring (not shown).

A color filter 123 is formed between each of the black matrixes 122. The color filter 123 is made of an organic material. The color filter 123 comprises three sub layers 123a, 123b and 123c which have different colors. An overcoat layer 124 and a common electrode 125 are formed on the black matrixes 122 and the color filter 123. The common electrode 125 is transparent and conductive.

The LCD device 100 according to the present invention is a semi-transmission type which includes a reflection region and a transmission region. Hereinafter, the light flow therethrough will be described.

Light which is emitted from a backlight unit (not shown) is transmitted to the transmission region. Then, the light is emitted to the outside through the thin film transistor substrate 110, the liquid crystal layer 130 and the color filter layer 120. While passing through the liquid crystal layer 130, the transmission of the light is controlled and a color is assigned to the light by the color filter 123. The light which is emitted from the backlight unit to the reflection region is transmitted back to the backlight unit by the reflection layer 117 and then recycled.

The light which is incident upon the reflection region from the outside through the color filter layer 120 is reflected by the reflection layer 117 back through the color filter substrate 120 to the outside. The amount and the color of the light is controlled and assigned while passing through the liquid crystal layer 130 and the color filter 123, respectively.

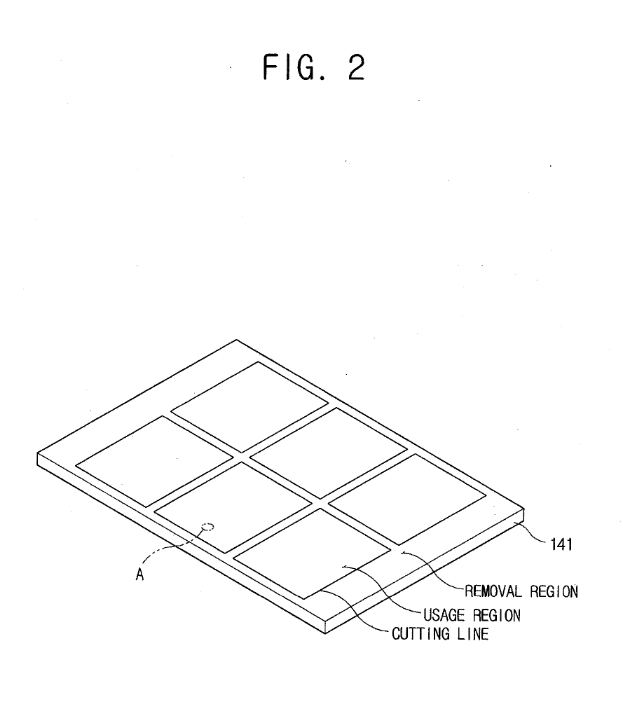

FIGS. 2 to 8b illustrate a method of manufacturing the LCD device 100 according to the first embodiment of the present invention. FIGS. 2 to 8b illustrate a process of forming the organic layer 113 of the thin film transistor substrate 110.

First, a mother insulating substrate 141 is provided as shown in FIG. 2. The mother insulating substrate 141 may comprise plastic or glass.

The thin film transistor substrate 110 in FIG. 1 is provided by forming a display element such as the thin film transistor 112 on the mother insulating substrate 141 and then by cutting it along a cutting line. In the first embodiment of the present invention, six thin film transistor substrates 110 are manufactured from one mother insulating substrate 141.

Six usage regions within the cutting line and a removal region between the usage regions are formed on the mother insulating substrate 141. The usage regions form a matrix shape.

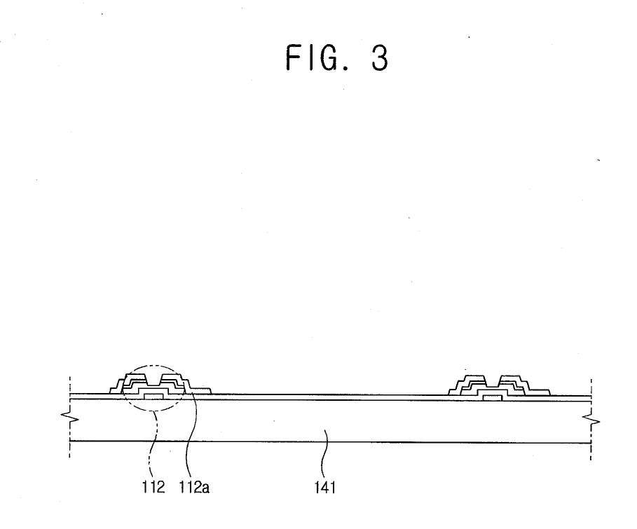

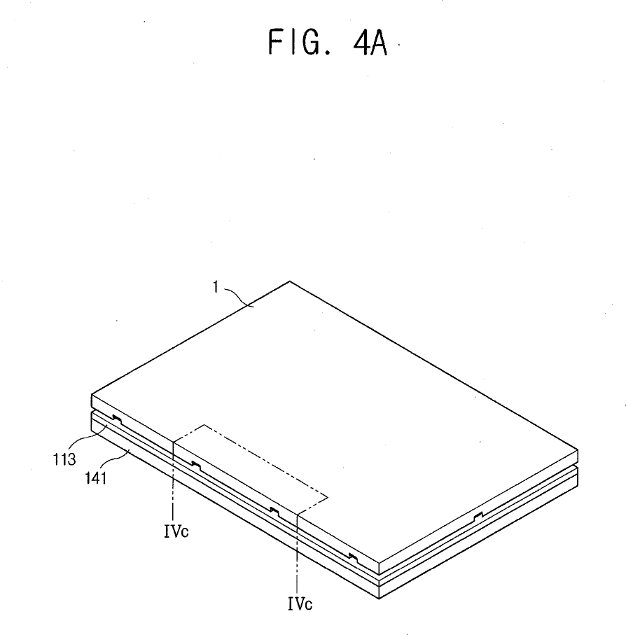

As shown in FIG. 3, the thin film transistors 112 are formed on the mother insulating substrate 141. The thin film transistors 112 comprise amorphous silicon as a semiconductor layer, which may be formed by a known method.

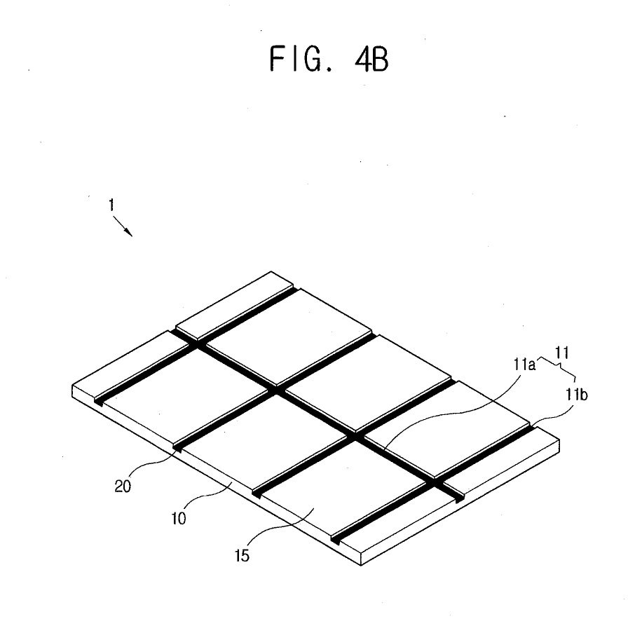

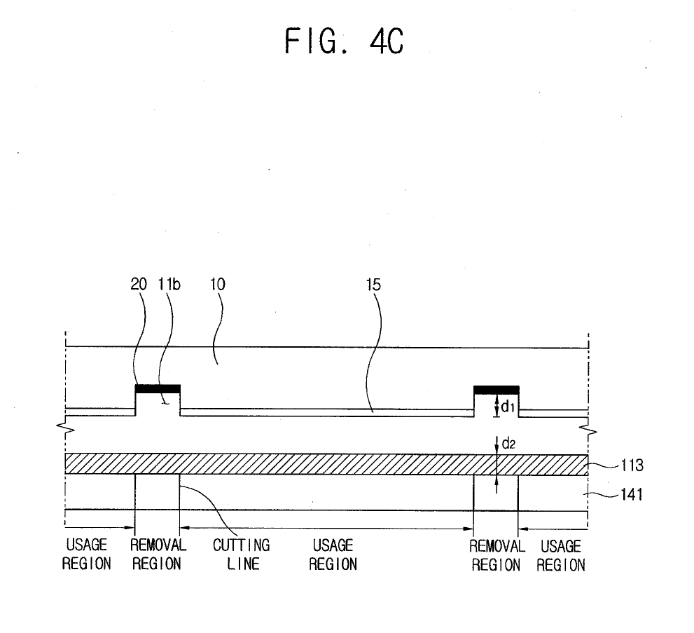

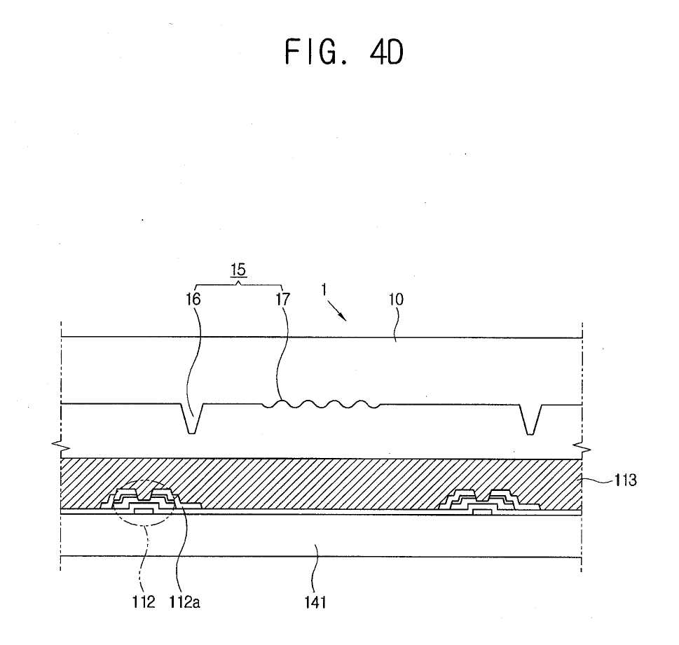

FIG. 3 is a partial cross-sectional view of a part A, i.e., the usage regions in FIG. 2. FIGS. 4d, 5d and 8b illustrate parts corresponding to FIG. 3.

As shown in FIGS. 4a to 4d, the organic layer 113 is coated on the thin film transistors 112. A mold 1 is arranged on the organic layer 113.

The organic layer 113 may be coated through a spin coating, slit coating or screen coating.

Hereinafter, the mold 1 arranged on the organic layer 113 will be described in detail.

The mold 1 comprises a mold main body 10 including a polymer. The mold main body 10 may comprise a light transmissive polymer, e.g., polydimethylsiloxane (PDMS) or polycarbonate (PC). PDMS has a good mold release property with the organic layer 113. Since the mold main body 10 comprises polymer, the mold 1 is soft and flexible.

A pattern part 15 is formed on a surface of the mold main body 10 facing the organic layer 113. The pattern part 15 is provided to correspond to the usage regions in FIG. 1. Thus, the pattern part 15 is arranged in a matrix shape.

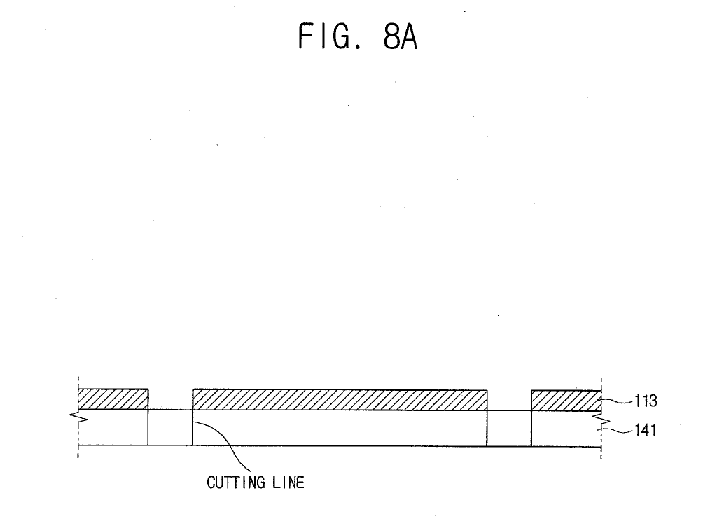

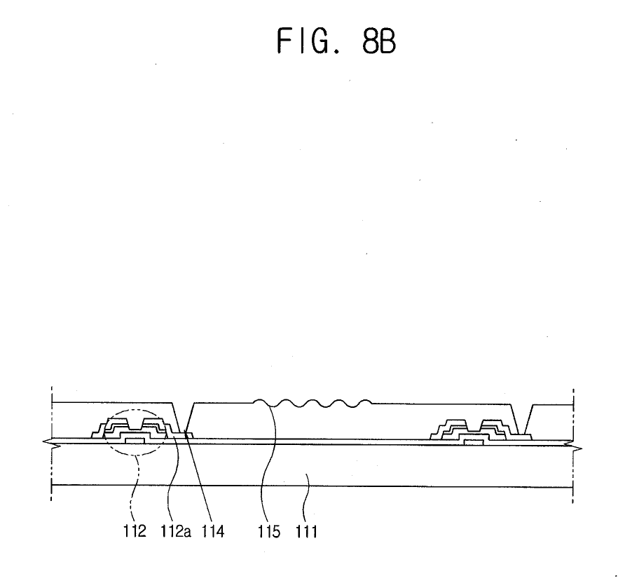

The pattern part 15 comprises a protruding part 16 to form the contact hole 114 (Shown best in FIGS. 1 and 8B) in the organic layer 113; and a concave embossing pattern 17 (Shown best in FIG. 4D) to form the embossing pattern 115 on the organic layer 113.

A groove 11 is formed between the pattern parts 15. The groove 11 is formed to correspond to the removal region in FIG. 1. The groove 11 is formed in a grid shape. The groove 11 comprises a first sub groove 11 a and a second sub groove 11b which are perpendicular to each other. The mold 1 has a rectangular shape. The first sub groove 11a is provided in parallel with a longer side of the mold 1, and the second sub groove 11b is provided in parallel with a shorter side thereof.

The depth d1 (see FIG. 4C) of the groove 11 may be 100 to 500 percent of a thickness d2 of the organic layer 113.

A light blocking layer 20 is formed on a lower part of the groove 11. The light blocking layer 20 blocks ultraviolet rays from being introduced to the organic layer 113. The light blocking layer 20 may comprise chrome, etc.

The mold 1 is arranged to direct the groove 11 and the pattern part 15 toward the organic layer 113. As the mold 1 is arranged and pressed at a normal pressure, air exists between the mold 1 and the organic layer 113.

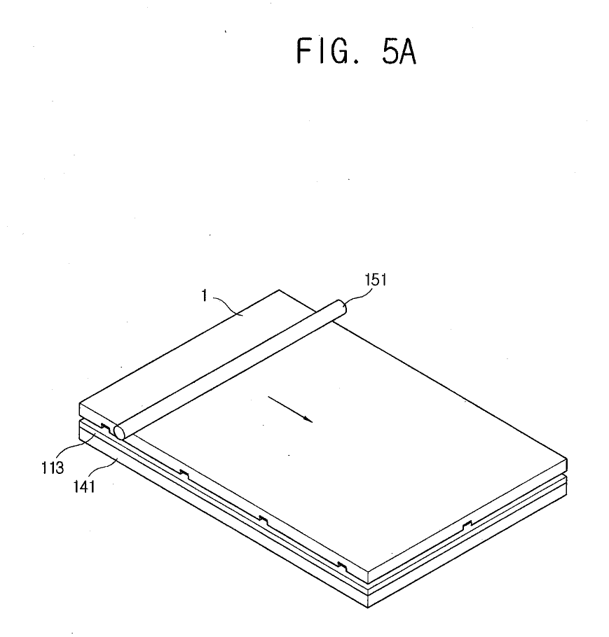

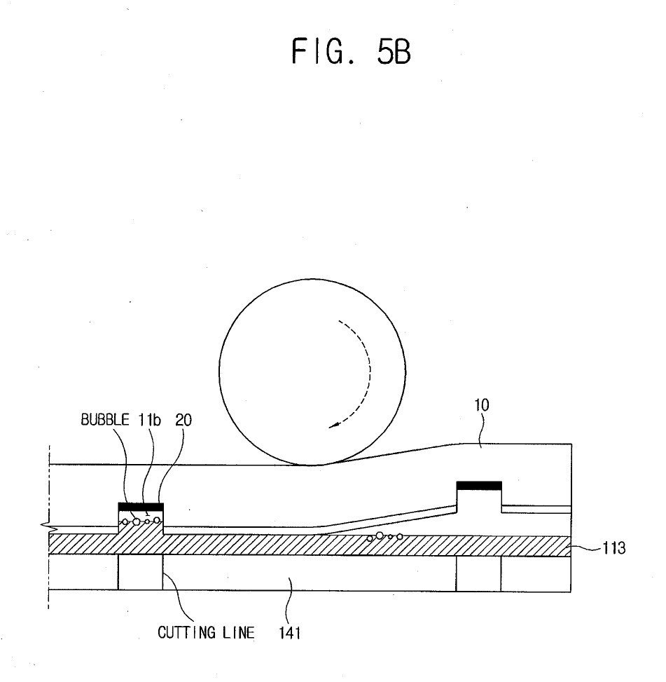

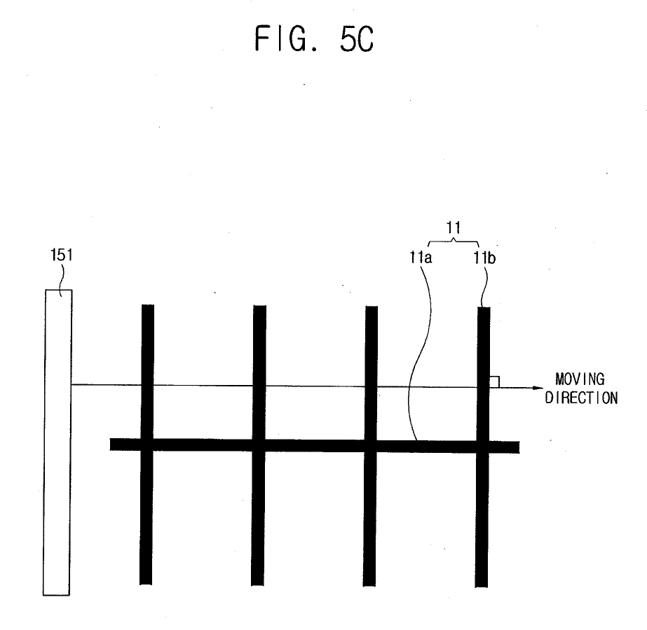

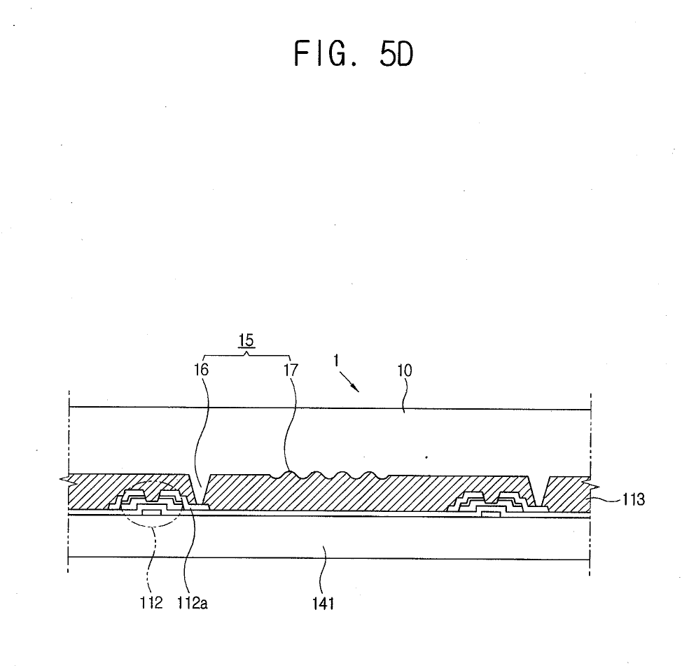

Then, the mold 1 is pressed to the organic layer 113 as shown in FIGS. 5a to 5d.

The mold 1 is pressed through a roller 151. The roller 151 sequentially presses the mold 1 to the organic layer 113 and moves in one direction.

FIG. 5c illustrates an extension direction of the groove 11 and a moving direction of the roller 151. The moving direction of the roller 151 is in parallel with the first sub groove 11a, and perpendicular to the second sub groove 11b. As the roller 151 has a structure extended in a direction perpendicular to the moving direction, the moving roller will be positioned parallel with the second sub groove 11b.

The mold 1 is pressed sequentially by the roller 151. When the mold 1 is pressed, the pattern part 15 is directly pressed into the organic layer 113 and transfers the pattern from the mold into the organic layer. A part of the organic layer 113 is introduced into the groove 11 while the mold 1 is pressed. Particularly, a large amount of organic layer 113 flows to the second sub groove 11b perpendicular to the pressure direction. Thus, more of the organic layer 113 under the groove 11 is transferred than under the pattern part 15.

First, the pattern part 15 of the mold 1 must be filled by the organic layer 113 for a precise transfer of the pattern part 15 of the mold 1 to the organic layer 113 on the mother insulating substrate 141.

In this case, a bubble should not be interposed between the organic layer 113 and the mold 1.

While pressing the mold 1 from left to right, i.e., toward a lengthwise direction of the first sub groove 11a, the bubble between the mold 1 and the organic layer 113 also moves from left to right. As the mold 1 is soft, the mold 1 is properly changed according to the pressure of the roller 151.

The bubbles in the organic layer 113 cannot move anymore once they are met by the second sub groove but rise from the organic layer 113 and are trapped in the space made between the organic layer 113 and the second sub groove.

Thus, the amount of bubbles which remain in the organic layer 113 under the pattern part 15 is reduced.

As shown in FIG. 5d, the protruding part 16 contacts the drain electrode 112a by the pressure, and the concave embossing pattern 17 is transferred to the organic layer 113 of the reflection region.

During this process, the organic layer 113 continues to receive a force in the lengthwise direction of the first sub groove 11a. When the pressure of the roller 151 is completed, a large amount of the organic layer 113 may flow to the circumference of the mother insulating substrate 141. In the present invention, the organic layer 113 moving in the lengthwise direction of the first sub groove 11a is introduced into the second sub groove 11b, thereby reducing the amount of the organic layer 113 flowing to the circumference of the mother insulating substrate 141. As the amount of overflowing organic layer 113 is reduced, the equipment for forming the organic layer 113 is less contaminated.

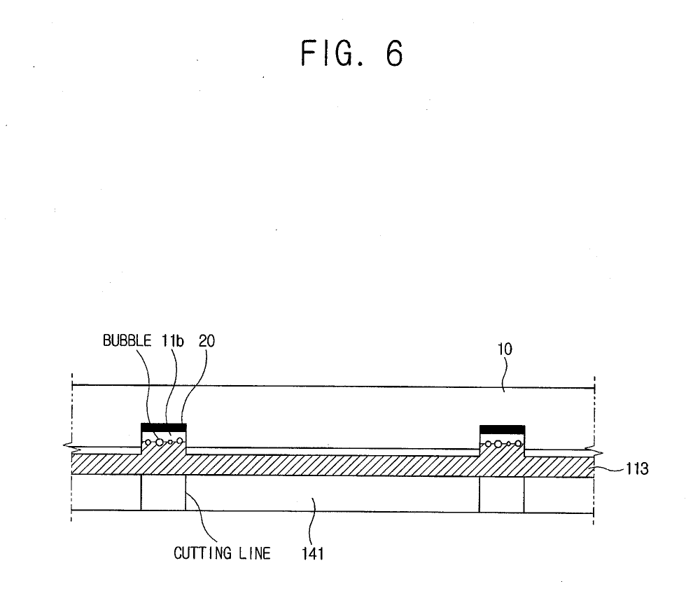

As shown in FIG. 6, the organic layer 113 is exposed to light by using the mold 1 as a mask. The organic layer 113 of the removal region corresponding to the light blocking layer 20 is not exposed to light. The organic layer 113 of the usage regions which are not covered by the light blocking layer 20 is exposed to light. The exposed organic layer 113 is cured while the unexposed organic layer 13 is not cured.

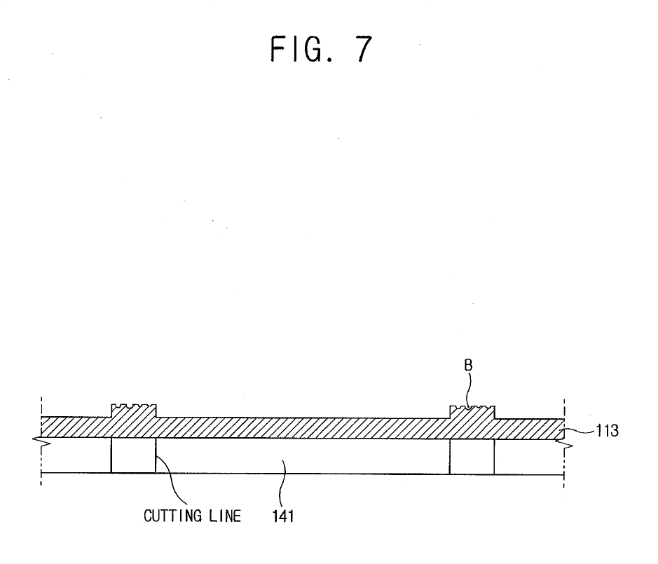

As shown in FIG. 7, the mold 1 is removed from the organic layer 113.

When adhesiveness between the mold 1 and the organic layer 113 is strong, the pattern of the organic layer 113 may be damaged while removing the mold 1 from the organic layer 113.

In the present invention, a part of the organic layer 113 covered by the light blocking layer 20 is not cured after the exposure, and the uncured part has weak adhesiveness with respect to the mold 1. Thus, the mold 1 may be removed from the organic layer 113 without difficulty.

The organic layer 113 corresponding to the removal region is deeper than the organic layer 113 corresponding to the usage regions. A pattern B (FIG. 7) is formed on an upper part of the organic layer 113 corresponding to the removal region, due to the bubbles.

FIGS. 8a and 8b illustrate the organic layer 113 after development. The organic layer 113 corresponding to the uncured region without a light exposure is removed. The organic layer 113 corresponding to the usage regions are formed with the contact hole 114 through which the drain electrode 112a is exposed, and the embossing pattern 115.

A pixel electrode 116 (FIG. 1) is formed and connected with the thin film transistors 112 through the contact hole 114. The reflection layer 117 is formed in the reflection region.

The color filter substrate 120 may be manufactured by a known method. The liquid crystal layer 130 is provided between the thin film transistor substrate 110 and the color filter substrate 120. Then, the thin film transistor substrate 110 and the color filter substrate 120 are adhered to each other. The thin film transistor substrate 110 and the color filter substrate 120 are cut along the cutting line in FIG. 2 to complete the LCD device 100 in FIG. 1.

In the first embodiment, the mold is sequentially pressed to the organic layer 113 by the roller 151, but not limited thereto. Alternatively, the mold 1 may be pressed through other means including compressed air.

The width of the groove 11 corresponds to that of the removal region, but not limited thereto. Alternatively, the width of the groove 11 may be smaller than that of the removal region.

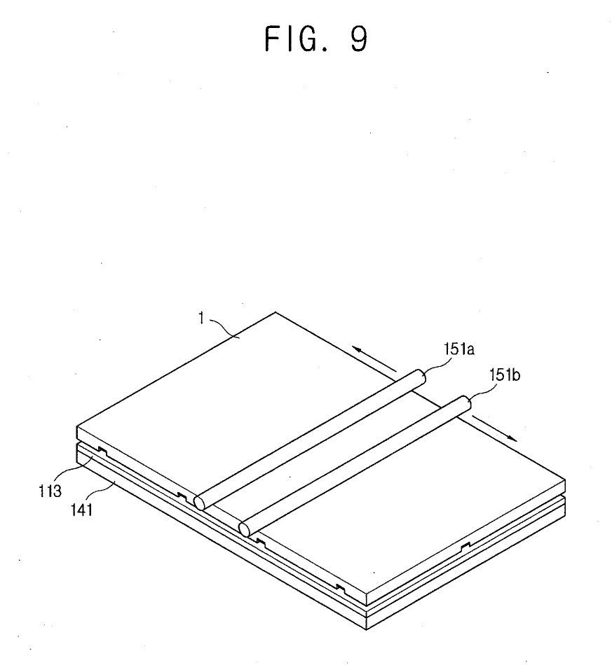

FIG. 9 illustrates another manufacturing method of the LCD device 100 according to the first embodiment of the present invention. FIG. 9 illustrates the mold 1 which is pressed to the organic layer 131.

A pair of rollers 151a and 151b is provided to press the mold 1 from a central part thereof to both side parts thereof. The mold 1 pressing time may be abridged with the manufacturing method illustrated in FIG. 8. The manufacturing method, however, is effective when the mother insulating substrate 141 is larger.

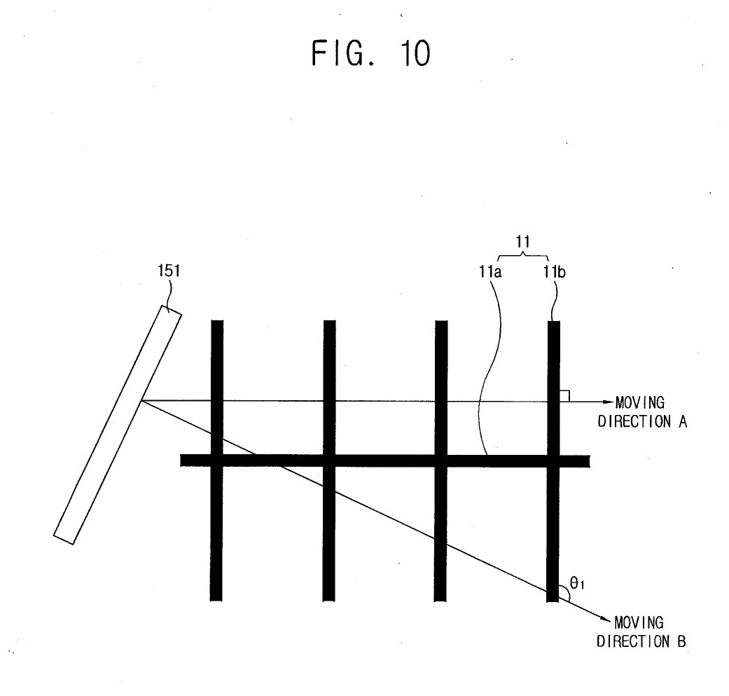

FIG. 10 illustrates another manufacturing method of the LCD device 100 according to the first embodiment of the present invention. FIG. 10 illustrates an arrangement between the groove 11 and the roller 151.

The roller 151 is positioned in a diagonal direction. The roller 151 may move in parallel with the first sub groove 11a along a moving direction A, or may move along a moving direction B while maintaining an angle between the roller 151 and with the first sub groove 11a constant.

When the roller 151 moves along the moving direction B, a large amount of bubbles may be also trapped in the first sub groove 11a.

The method of manufacturing the organic layer formed with the embossing pattern is described above. However, the present invention is not limited to the production of the organic layer formed with the embossing pattern. Alternatively, the present invention can be applicable to manufacturing a color filter or to patterning a photosensitive layer. The patterned photosensitive layer is need for etching an inorganic layer or a metal layer.

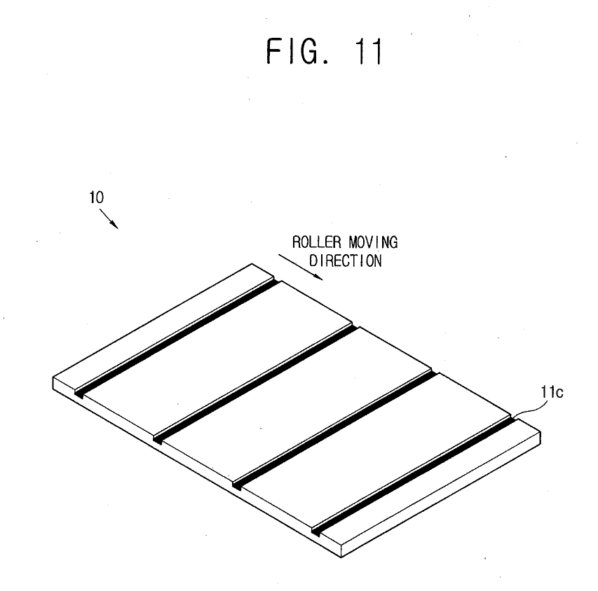

FIG. 11 is a perspective view of another mold for manufacturing the LCD device 100 according to the present invention.

Grooves in a mold 1 are formed parallel with each other. A roller moving direction is not in parallel with a groove extension direction. Preferably, the roller moving direction is perpendicular to the groove extension direction.

As described above, the present invention provides a method for manufacturing a display device which reduces errors in patterning an organic layer, due to a bubble.

Also, the present invention provides a mold for manufacturing a display device which reduces errors in patterning an organic layer, due to a bubble.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A method of manufacturing a display device, comprising:
providing a mother insulating substrate which comprises usage regions arranged in a matrix shape, and a removal region formed between the usage regions;
forming an organic layer on the mother insulating substrate;
arranging a mold formed with a pattern part corresponding to the usage regions and a groove corresponding to at least a part of the removal region and formed in a grid shape, on the organic layer;
moving a pressure means and sequentially pressing the mold to the organic layer; and
separating the mold from the organic layer.

2. The method according to claim 1, wherein a moving direction of the pressure means maintains a predetermined angle with respect to an extension direction of the groove.

3. The method according to claim 2, wherein the moving direction of the pressure means is perpendicular to the extension direction of the groove.

4. The method according to claim 3, wherein the pressure means comprises a roller.

5. The method according to claim 1, wherein the organic layer comprises a photosensitive material.

6. The method according to claim 5, wherein the mold comprises a mold main body which comprises light transmissive polymer and a light blocking layer which is formed on the mold main body to correspond to the removal region.

7. The method according to claim 6, wherein the light blocking layer is provided within the groove.

8. The method according to claim 6, wherein the mold main body comprises polydimethylsiloxane (PDMS) or polycarbonate (PC).

9. The method according to claim 6, further comprising: exposing the organic layer to light by using the mold pressed to the organic layer, as a mask.

10. The method according to claim 1, wherein a depth of the groove is 100 percent to 500 percent of a thickness of the organic layer.

11. The method according to claim 1, wherein the mold is pressed to the organic layer at a normal pressure.

12. The method according to claim 1, further comprising:
forming a thin film transistor having a drain electrode, on the mother insulating substrate, wherein the organic layer is formed on the thin film transistor.

13. The method according to claim 12, wherein the pattern part is formed with a concave embossing pattern and a protruding part corresponding to the drain electrode.

14. The method according to claim 13, wherein an end part of the protruding part contacts the drain electrode while the mold is pressed to the organic layer.

15. A mold for manufacturing a display device which comprises a mold main body, comprising: a pattern part being formed on a surface of the mold main body in a matrix shape and a groove being formed between the pattern parts wherein the groove is formed in a grid shape.

16. The mold according to claim 15, further comprising: a light blocking layer which is formed in the groove.

17. The mold according to claim 15, wherein the mold main body comprises polymer.

18. The mold according to claim 15, wherein the mold main body is light-transmissive.
